(19) United States
(12) Patent Application Publication
(10) Pub. No.: US 2004/0188741 A1
(43) Pub. Date: Sep. 30, 2004

(54) Vertical MOS transistor

(76) Inventor: Hirofumi Harada, Chiba-shi (JP)

Correspondence Address: ADAMS & WILKS, 31st FLOOR, 50 BROADWAY, NEW YORK, NY, 10004, US

(21) Appl. No.: 10/803,779

(22) Filed: Mar. 18, 2004

(30) Foreign Application Priority Data
Mar. 19, 2003 (JP) 2003-075344

(51) Int. Cl. H01L 21/336

(52) U.S. Cl. 257/302

(57) ABSTRACT

A vertical MOS transistor which is reduced in size and cost and which has high drive performance, reliability and yield is provided. Also provided is a method of manufacturing the vertical MOS transistor. A polycrystalline silicon gate electrode is buried halfway down a trench and an intermediate insulating film is put on top of the gate electrode to fill the rest of the trench. The intermediate insulating film then receives etch-back to form a metal electrode in a self-aligning manner without intervention of a contact hole. This eliminates the need to allow a layout margin for misalignment or the like and therefore makes it possible to reduce a transistor area. This also gives the transistor high reliability since the metal electrode is leveled thoroughly.

### BACKGROUND OF THE INVENTION

1. Field of the Invention

The present invention relates to a vertical MOS transistor having a trench structure and to a method of manufacturing the same.

2. Description of the Related Art

FIG. 2 is a schematic sectional view of a conventional vertical MOS transistor that has a trench structure. A semiconductor substrate shown in FIG. 2 is prepared by forming, through epitaxial growth, on a heavily doped substrate 1 of a first conductivity type which serves as a drain region, a first conductivity type layer 2 doped with an impurity that is used to dope the substrate 1 in a concentration lower than that of the substrate 1. A surface of the thus prepared semiconductor substrate is subjected to impurity implantation and subsequent high temperature heat treatment at 1,000° C. or more to form a diffusion region 3 of a second conductivity type which is called a body region. The other portions of the surface of the substrate constitute a high concentration impurity region 7 of the first conductivity type which serves as a source region and a heavily doped body contact region 8 of the second conductivity type which fixes an electric potential of the body region by ohmic contact.

The first conductivity type source region- and the second conductivity type body contact region are usually arranged to come into contact with each other on the surface as shown in FIG. 2, so that the two regions have the same electric potential. The source region 7 and the body contact region 8 are also electrically connected to each other through one contact hole formed above the regions 7 and 8. The single crystal silicon is etched to pierce the first conductivity type source region and form a silicon trench 4. A gate insulating film 5 and a polycrystalline silicon film 6, which contains an impurity in high concentration to serve as a gate electrode, are buried in the silicon trench. A rear surface of the semiconductor substrate has a heavily doped region of the first conductivity type which is connected to a drain metal electrode 16.

The above structure allows the semiconductor device to function as a vertical MOS transistor in which a current flowing from a drain region, which is composed of the rear side first conductivity type heavily doped region and the first conductivity type epitaxial region, to a source region, which is composed of the front side first conductivity type heavily doped region, is controlled by the gate buried in the trench through the gate insulating film formed on side walls of the trench. This method is applicable to an N-channel transistor and a P-channel transistor both by reversing the conductivity type between N and P.

The vertical MOS transistor having the trench structure is characterized by forming a completely vertical channel and therefore can employ a technique of miniaturization in a planar direction. Accordingly, advancement in miniaturization technique has reduced a transistor area in the planar direction and the reduction contributes to a recent increase in amount of drain current per device unit area.

In practice, the sectional structure shown in FIG. 2 is repeated several times to thereby widen a channel width and increase the drain current amount. A MOS transistor having an arbitrary drive performance is obtained in this way.

The basic structure and manufacturing method of this type of vertical MOS transistor are outlined in, for example, U.S. Pat. No. 4,767,722 B.

However, the vertical MOS transistor structure and manufacturing method have the following problems:

First of all, the contact hole extended between the heavily doped source region and the body contact region necessitates allowing a margin in case the two regions are misaligned and therefore the device area has to be set large. In addition, a margin for misalignment has to be counted in when setting the distance from the trench pattern in order to avoid opening a current path between the gate electrode and a source electrode. These present obstacles in miniaturizing the vertical MOS transistor and keep the transistor from being reduced in size and cost, and from having improved drive performance.

Secondly, as mentioned above, recent vertical MOS transistors are often increased in drain current density owing to miniaturization and are accordingly increased in metal deposit thickness from the viewpoints of reliability and lowering the resistance.

Sputtering is generally used to form the source metal electrode in the contact hole above the heavily doped source region. The anisotropism of the deposit causes the metal to poorly cover a contact edge portion as the one indicated by 17 in FIG. 2, and the film thickness in the edge portion is substantially half the thickness of the flat portion, or ⅓ or less in worst cases. In order to avoid current concentration on the edge portion and resultant wire breakage and lowering of reliability, the metal film has to be formed thicker. However, a thicker metal film is undesirable for throughput and pattern processing accuracy and leads to an increase in material cost.

### SUMMARY OF THE INVENTION

The present invention has been made in view of the above, and an object of the present invention is therefore to provide a vertical MOS transistor which is reduced in size and cost and which has high drive performance, reliability and yield, and a method of manufacturing the vertical MOS transistor.

In order to achieve the above-mentioned object, the present invention provides a vertical MOS transistor, including: a semiconductor substrate of a first conductivity type; an epitaxial growth layer of the first conductivity type which is formed on the semiconductor substrate; a body region of a second conductivity type which is formed on the epitaxial growth layer; a heavily doped body contact region of the second conductivity type which is formed on a part of a surface of the second conductivity type body region; a heavily doped source region of the first conductivity type which is formed on a part of the surface of the second conductivity type body region that is not covered with the heavily doped body contact region; a silicon trench piercing the second conductivity type body region and the first conductivity type source region to reach an inner part of the first conductivity type epitaxial growth layer; a gate insulating film formed along walls and bottom of the silicon trench; a heavily doped polycrystalline silicon gate buried in the silicon trench to a level of the first conductivity type source region while surrounded by the gate insulating film; an intermediate insulating film formed on the polycrystalline silicon gate in the silicon trench to reach a surface of the semiconductor substrate; a metallic source electrode having a flat surface to be in contact with the intermediate insulating film, the heavily doped source region, and the heavily doped body contact region; and a metallic drain electrode connected to a rear surface of the semiconductor substrate.

Further, in the vertical MOS transistor, an insulator is provided on the side walls of the silicon trench above the heavily doped polycrystalline silicon gate.

Further, in the vertical MOS transistor, the insulator provided on the side walls of the silicon trench is a silicon nitride film.

Further, in the vertical MOS transistor, the heavily doped polycrystalline silicon gate buried in the silicon trench is 0.5 μm to 1.0 μm down from the top of the trench.

### BRIEF DESCRIPTION OF THE DRAWINGS

In the accompanying drawings:

FIG. 1 is a schematic sectional view of a vertical MOS transistor according to the present invention;

FIG. 2 is a schematic sectional view of a conventional vertical MOS transistor;

FIG. 3 is a schematic sectional view showing Step 1 of a vertical MOS transistor manufacturing method according to the present invention;

FIG. 4 is a schematic sectional view showing Step 2 of the vertical MOS transistor manufacturing method according to the present invention;

FIG. 5 is a schematic sectional view showing Step 3 of the vertical MOS transistor manufacturing method according to the present invention;

FIG. 6 is a schematic sectional view showing Step 4 of the vertical MOS transistor manufacturing method according to the present invention;

FIG. 7 is a schematic sectional view showing Step 5 of the vertical MOS transistor manufacturing method according to the present invention;

FIG. 8 is a schematic sectional view showing Step 6 of the vertical MOS transistor manufacturing method according to the present invention;

FIG. 9 is a schematic sectional view showing Step 7 of the vertical MOS transistor manufacturing method according to the present invention;

FIG. 10 is a schematic sectional view showing Step 8 of the vertical MOS transistor manufacturing method according to the present invention;

FIG. 11 is a schematic sectional view showing Step 9 of the vertical MOS transistor manufacturing method according to the present invention; and

FIG. 12 is a schematic sectional view of a vertical MOS transistor according to another embodiment of the present invention.

### DETAILED DESCRIPTION OF THE PREFERRED EMBODIMENTS

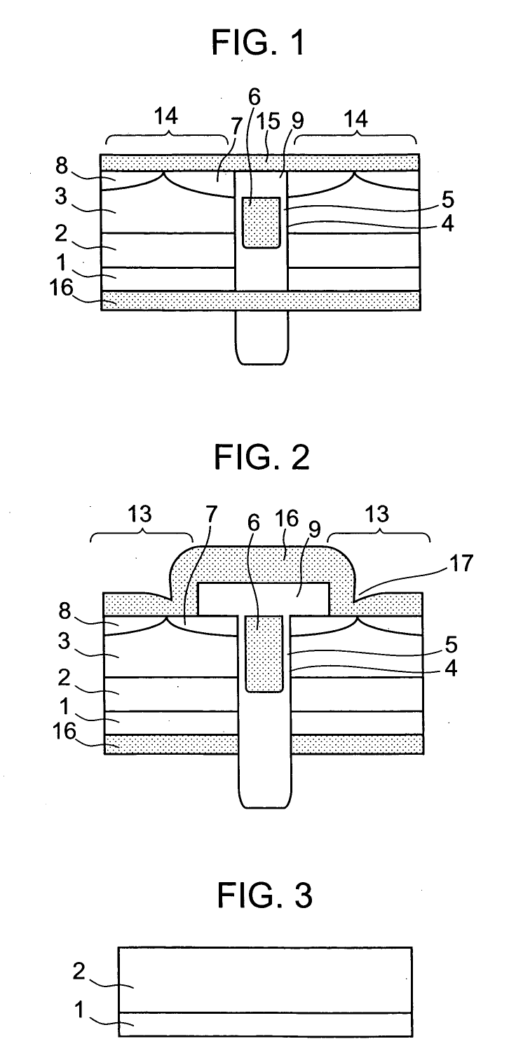

Embodiments of the present invention will be described below with reference to the accompanying drawings. FIG. 1 is a schematic sectional view of an N-channel vertical MOS transistor according to the present invention. A semiconductor substrate shown in FIG. 1 is prepared by forming, through epitaxial growth, on a heavily doped substrate 1 of a first conductivity type which serves as a drain region, a first conductivity type layer 2 doped with an impurity that is used to dope the substrate 1 in a concentration lower than that of the substrate 1. A surface of the thus prepared semiconductor substrate is subjected to impurity implantation and subsequent high temperature heat treatment at 1,000° C. or more to form a diffusion region 3 of a second conductivity type, which serves, as a body region. The other portions of the surface of the substrate constitute a high concentration impurity region 7 of the first conductivity type which serves as a source region and a heavily doped body contact region 8 of the second conductivity type which fixes an electric potential of the body region by ohmic contact. The regions 7 and 8 are turned conductive by the same metal film. As a contact between the regions 7 and 8, a silicon surface is uniformly exposed except in a silicon trench to bring the metal film into contact with the semiconductor substrate flatly.

The metal film is prevented from coming into contact with a gate electrode 6, which is formed from heavily doped polycrystalline silicon in the trench, by burying the heavily doped polycrystalline silicon halfway down the trench and forming an insulating film on top of the polycrystalline silicon.

A heavily doped region of the first conductivity type is formed on a rear surface of the semiconductor substrate and connected to a drain metal electrode as in conventional cases.

The heavily doped polycrystalline silicon gate electrode 6 in the trench is desirably 0.5 μm or deeper from the top of the trench. This is for preventing a capacitor that is formed between the gate electrode and a source metal electrode 15 immediately above the gate electrode from impairing high frequency characteristics. Considering the diffusion depth of the heavily doped source region, it is desirable to set the heavily doped polycrystalline silicon gate electrode 6 to 1 μm or shallower from the top of the trench. If the source region is let diffuse deeper than that through heat treatment, the depth of the body region is accordingly changed.

In short, the heavily doped polycrystalline silicon gate electrode 6 is preferably set between 0.5 μm and 1 μm down from the top of the trench.

The above structure allows, as in conventional cases, the semiconductor device to function as a vertical MOS transistor in which a current flowing from a drain region, which is composed of the rear side first conductivity type heavily doped region and the first conductivity type epitaxial region, to a source region, which is composed of the front side first conductivity type heavily doped region, is controlled by the gate, which is formed from polycrystalline silicon buried in the trench, through the gate insulating film formed on side walls of the trench.

Furthermore, the vertical MOS transistor of this embodiment has no need to allow a margin for misalignment among a contact hole, a heavily doped source region and a heavily doped body region, nor to set aside a space for misalignment between a contact hole and a trench which has been a problem in the conventional example. The transistor therefore takes up a smaller area, is reduced in size, and is increased in current.

Moreover, the metal film is thoroughly leveled as shown in FIG. 1 unlike the conventional example in which metal is deposited unevenly. This makes it possible to form a metal film of uniform thickness by the conventional sputtering method while avoiding current concentration on a single portion. A highly reliable source electrode thus can be formed from a film that is thinner than in conventional cases.

This method is applicable to an N-channel transistor and a P-channel transistor both by reversing the conductivity type between N and P.

A method of manufacturing a vertical MOS transistor according to the present invention will be described with reference to FIGS. 3 to 12, and the description takes an N-channel vertical MOS transistor as an example.

First, a <100> orientation semiconductor substrate is prepared by forming an N type lightly doped epitaxial layer 2 to a thickness of several μm to several tens μm on an N type heavily doped substrate 1 (FIG. 3). The N type heavily doped substrate 1 is doped with As or SB in a concentration that gives the substrate a resistivity of 0.001 Ω·cm to 0.01 Ω·cm. The N type lightly doped epitaxial layer 2 is doped with P in a concentration of 2e14/cm³ to 4e16/cm³. The thickness and impurity concentration of the N type epitaxial layer are arbitrarily set in accordance with the necessary drain-source withstand voltage and current drive performance.

Next, a region to later serve as a body of the vertical MOS transistor is formed by subjecting the semiconductor substrate to implantation of B and subsequently to heat treatment. Obtained as a result is a P type body region 3 having an impurity concentration of 2e16/cm³ to 5e16/cm³ and a thickness of several μm to over ten μm. Then single crystal silicon is exposed in a region where a trench is to be formed while the rest is covered with an oxide film mask or a resist mask in preparation for anisotropic etching by RIE. The exposed silicon is etched until the body region is pierced and a silicon trench is thus formed.

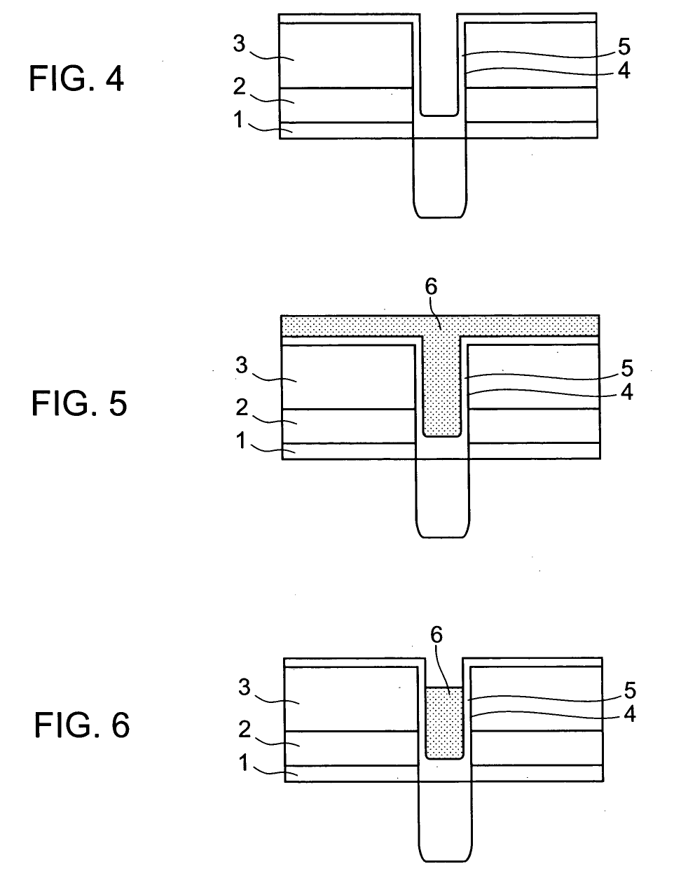

Corners of the trench are rounded by a well known method such as high temperature sacrificial oxidation or isotropic dry etching. Then a gate insulating film is formed on the side walls and bottom of the trench (FIG. 4).

Thereafter, the trench is completely filled with polycrystalline silicon that contains a high concentration of impurities by depositing the polycrystalline silicon in accordance with the trench width until the deposit obtains a level surface (FIG. 5). For instance, when the trench width is 0.8 μm, the polycrystalline silicon should be deposited to a thickness of 0.4 μm or more. The polycrystalline silicon film containing a high concentration of impurities can be formed by any method; polycrystalline silicon that contains no impurity is deposited first and then doped with an impurity through thermal diffusion or ion implantation, or an impurity is introduced while polycrystalline silicon is deposited.

Next, the polycrystalline silicon on the surface of the semiconductor substrate and that inside the silicon trench are removed by etch-back until at least the surface of the semiconductor substrate is completely free of the polycrystalline silicon. In the etch-back step, the polycrystalline silicon in the trench is intentionally etched down to a depth of 0.5 μm to 1.0 μm from the top of the trench (FIG. 6). The polycrystalline silicon deposit depth from the top of the trench is adjusted based on the etching time detected from a change in radical amount or the like as the semiconductor substrate surface is exposed during the polycrystalline silicon etching.

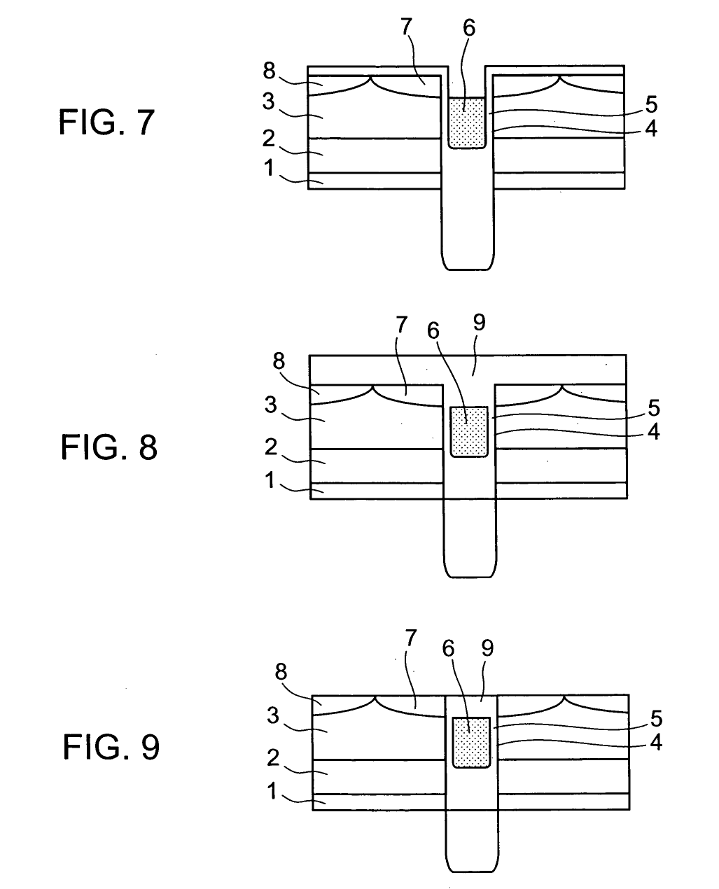

Similar to the usual MOS manufacturing process, the next step includes implantation of As for forming a heavily doped source region, implantation of B or BF₂ for forming a heavily doped body contact region, and activation treatment for the impurities (FIG. 7). In this step, the heavily doped source region is diffused until it reaches the polycrystalline silicon in the silicon trench.

Next, an intermediate insulating film 9 is formed by deposition to level out surface irregularities caused by the heavily doped polycrystalline silicon which is buried halfway down the trench. The surface irregularities are evened out by, for example, forming through CVD a low softening point oxide film of BSG (boron silicate glass), PSG (phosphor silicate glass), BPSG (boron-phosphor silicate glass) or the like with TEOS (tetraethylorthosilicate) or NSG (non-silicate glass) as a base and then annealing the film (FIG. 8).

The intermediate insulating film is then etched by etch-back to expose the heavily doped source region 7 and the heavily doped body contact region 8 while leaving the intermediate insulating film inside the trench (FIG. 9).

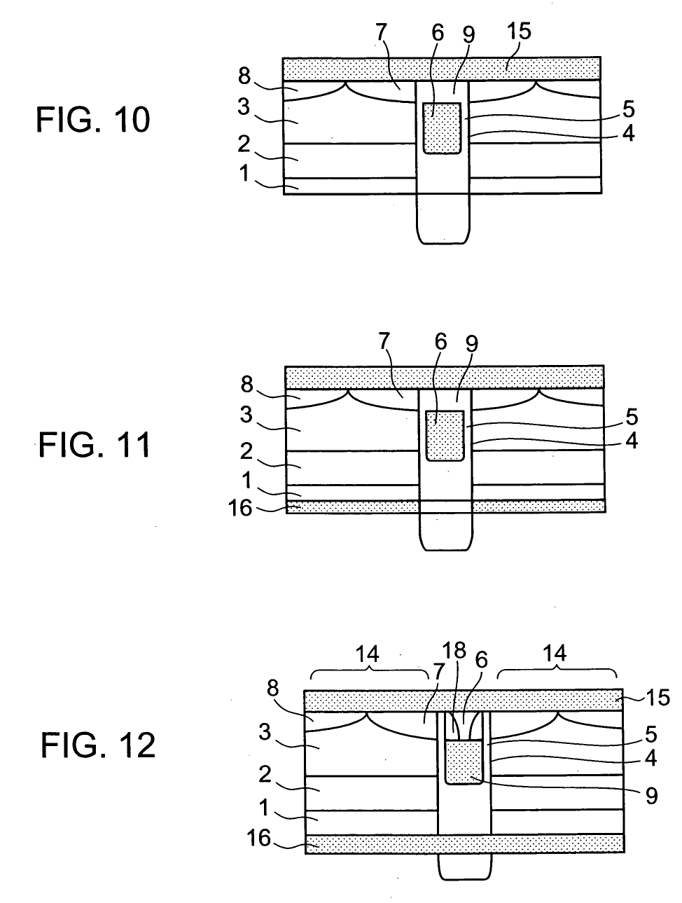

Formed next is a metal film 15 for giving the source and body electric potentials (FIG. 10). Unlike conventional cases in which the heavily doped source region and the heavily doped body region alone are selectively brought into contact with the metal film by forming a contact hole in the intermediate insulating film, the present invention can establish a metal contact while the metal film is formed on the entire transistor region since the heavily doped polycrystalline silicon 6 in the trench is covered with the intermediate insulating film. In addition, the metal film is highly flat due to the fact that the substrate surface on which the metal film is formed is previously leveled by etch-back.

The last step includes forming a surface protection film, grinding the rear surface of the substrate, and forming a rear surface drain metal electrode (details are omitted from the drawing) to complete the vertical MOS transistor of the present invention (FIG. 11).

The vertical MOS transistor of the present invention which is given the above-described structure through the above-described manufacturing process has the following characteristics:

One, the source metal electrode can be formed in a self-aligning manner without needing to allow a margin for misalignment among a contact hole, a heavily doped source region and a heavily doped body region, nor to set aside a space for misalignment between a contact hole and a silicon trench. With a reduction in area, the transistor can be reduced in cost, or reduced in size and increased in drive current.

Two, the source metal electrode of the present invention does not suffer from local thinning unlike the conventional example and the metal film therefore has a level surface. The flat metal film makes uniform current flow possible, thereby improving the wiring reliability and preventing an increase in thickness of the metal film which leads to an increase in cost and the throughput from lowering. With the processibility improved, the vertical MOS transistor can be manufactured stably.

FIG. 12 shows another embodiment of the present invention. In FIG. 12, side spacers are formed from a nitride film or the like on the side walls of the trench above the heavily doped polycrystalline silicon. In general, electric field concentration tends to take place in an oxide film between heavily doped polycrystalline silicon and a heavily doped source region in a vertical MOS transistor, and the oxide film in this portion is liable to undergo film quality degradation due to etching or other damage brought upon in the manufacturing process. These are two factors that readily cause lowering of the oxide film withstand voltage, lowering of the long-term reliability, and other defects. The present invention is capable of avoiding such defects by forming a nitride film in this portion in this embodiment as shown in FIG. 12.

The side spacers can be formed by depositing a nitride and subjecting the deposit to anisotropic dry etching in the step of FIG. 7, which shows a part of the manufacturing process of the present invention.

The present invention can provide a vertical MOS transistor that is reduced in size and has high drive performance. The present invention not only provides a highly reliable vertical MOS transistor but also lowers the price of the transistor by cutting the manufacturing process short, reducing the material cost, and improving the yield.

What is claimed is:

1. A vertical MOS transistor comprising:
a semiconductor substrate of a first conductivity type;
an epitaxial growth layer of the first conductivity type which is formed on the semiconductor substrate;
a body region of a second conductivity type which is formed on the epitaxial growth layer;
a heavily doped body contact region of the second conductivity type which is formed on a part of a surface of the second conductivity type body region;
a heavily doped source region of the first conductivity type which is formed on a part of the surface of the second conductivity type body region that is not covered with the heavily doped body contact region;
a silicon trench piercing the second conductivity type body region and the first conductivity type source region to reach an inner part of the first conductivity type epitaxial growth layer;
a gate insulating film formed along walls and bottom of the silicon trench;
a heavily doped polycrystalline silicon gate buried in the silicon trench to a level of the first conductivity type source region while surrounded by the gate insulating film;
an intermediate insulating film formed on the polycrystalline silicon gate in the silicon trench to reach a surface of the semiconductor substrate;
a metallic source electrode having a flat surface to be in contact with the intermediate insulating film, the heavily doped source region, and the heavily doped body contact region; and
a metallic drain electrode connected to a rear surface of the semiconductor substrate.

2. A vertical MOS transistor according to claim 1, wherein an insulator is provided on the side walls of the silicon trench above the heavily doped polycrystalline silicon gate.

3. A vertical MOS transistor according to claim 2, wherein the insulator provided on the side walls of the silicon trench is a silicon nitride film.

4. A vertical MOS transistor according to claim 3, wherein the heavily doped polycrystalline silicon gate buried in the silicon trench is 0.5 μm to 1.0 μm down from the top of the trench.

5. A vertical MOS transistor according to claim 2, wherein the heavily doped polycrystalline silicon gate buried in the silicon trench is 0.5 μm to 1.0 μm down from the top of the trench.

6. A vertical MOS transistor according to claim 1, wherein the heavily doped polycrystalline silicon gate buried in the silicon trench is 0.5 μm to 1.0 μm down from the top of the trench.
